(19) United States
(12) Patent Application Publication
(10) Pub. No.: US 2014/0001556 A1
(43) Pub. Date: Jan. 2, 2014

(54) SEMICONDUCTOR DEVICE AND METHOD FOR MANUFACTURING SEMICONDUCTOR DEVICE

(71) Applicant: KABUSHIKI KAISHA TOSHIBA, Tokyo (JP)

(72) Inventor: Shinya ARAI, Kanagawa (JP)

(73) Assignee: Kabushiki Kaisha Toshiba, Tokyo (JP)

(21) Appl. No.: 13/774,788

(22) Filed: Feb. 22, 2013

(30) Foreign Application Priority Data
Jul. 2, 2012 (JP) 2012-148517

(51) Int. Cl. H01L 29/78; H01L 29/66

(52) U.S. Cl. CPC H01L 29/7831; H01L 29/66484
USPC 257/365; 438/283

(57) ABSTRACT

A memory cell and a peripheral circuit each having a gate electrode are formed on a semiconductor substrate. The periphery of the gate electrodes is covered with an organic insulating layer. A stopper film and a hard mask layer are formed on the gate electrodes and the organic insulating layer, and contact holes are formed between the gate electrodes in a self-aligning manner. Contact electrodes are embedded in the contact holes to provide electrical connection to diffusion layers formed on the semiconductor substrate on either side of each gate electrode.

### CROSS-REFERENCE TO RELATED APPLICATION

This application is based upon and claims the benefit of priority from Japanese Patent Application No. 2012-148517, filed Jul. 2, 2012, the entire contents of which are incorporated herein by reference.

### FIELD

Embodiments described herein relate generally to a semiconductor device and a method for manufacturing the semiconductor device.

### BACKGROUND

As the level of miniaturization in semiconductor devices increases, the pitch of contacts becomes narrower, and as a result the alignment of hole patterns through lithography becomes difficult. For this reason, a technique that forms contact holes in a self-aligned state (self-alignment) by using a gate hard mask as an etching mask is sometimes employed.

### DESCRIPTION OF THE DRAWINGS

FIG. 1A depicts a cross section of a cell array part of a semiconductor device of a first embodiment, and FIG. 1B depicts a cross section of a peripheral circuit part of the semiconductor device of the first embodiment.

FIG. 2A depicts a cross section of a cell array part of a semiconductor device of a second embodiment, and FIG. 2B depicts a cross section of a peripheral circuit part of the semiconductor device of the second embodiment.

FIGS. 3A, 4A, and 5A depict cross sections of a cell array part of a semiconductor device of a third embodiment during manufacture, and FIGS. 3B, 4B, and 5B depict cross sections of a peripheral circuit part of the semiconductor device of the third embodiment during manufacture.

FIG. 6A and FIG. 6B are plan views showing a resist pattern shape that is used in bit contact formation during manufacture of the cell array part of the semiconductor device of the third embodiment.

FIGS. 7A, 8A, 9A, 10A, 11A, 12A, 13A, and 14A depict cross sections of the cell array part of the semiconductor device of the third embodiment during manufacture, and FIGS. 7B, 8B, 9B, 10B, 11B, 12B, 13B, and 14B depict cross sections of the peripheral circuit part of the semiconductor device of the third embodiment during manufacture.

FIG. 15A depicts a cross section of a cell array part of a semiconductor device of a fourth embodiment, and FIG. 15B depicts a cross section of a peripheral circuit part of the semiconductor device of the fourth embodiment.

FIG. 16A depicts a cross section of a cell array part of a semiconductor device of a fifth embodiment, and FIG. 16B depicts a cross section of a peripheral circuit part of the semiconductor device of the fifth embodiment.

FIG. 17A and FIG. 17B are plan views showing a resist pattern shape that is used in bit contact formation during manufacture of a cell array part of a semiconductor device of a sixth embodiment.

FIGS. 18A, 19A, 20A, 21A, 22A, 23A, 24A, 25A, 26A, 27A, and 28A depict cross sections of a cell array part of the semiconductor device of the sixth embodiment, and FIGS. 18B, 19B, 20B, 21B, 22B, 23B, 24B, 25B, 26B, 27B, and 28B depict cross sections of a peripheral circuit part of the semiconductor device of the sixth embodiment.

### DETAILED DESCRIPTION

Embodiments provide a semiconductor device and a method of manufacturing the semiconductor device that provides improved controllability of contact hole formation through self-alignment.

In general, the embodiments will be explained in detail with reference to the attached figures. Here, the present disclosure is not limited to the embodiments described herein.

According to the embodiments, a semiconductor device is provided with gate electrodes, impurity diffusion layers, side wall insulating films, an organic insulating layer, an inorganic insulating layer, and contact electrodes. The gate electrodes are formed on a semiconductor substrate. The impurity diffusion layers are arranged so that they sandwich a channel region that is formed on the semiconductor substrate under the gate electrodes. The side wall insulating films are formed at the side walls of the gate electrodes. The organic insulating layer covers the periphery of the gate electrodes. The inorganic insulating layer is formed on the gate electrodes and the organic insulating layer. The contact electrodes are embedded in the inorganic insulating layer and the organic insulating layer and are connected to the impurity diffusion layer.

### First Embodiment

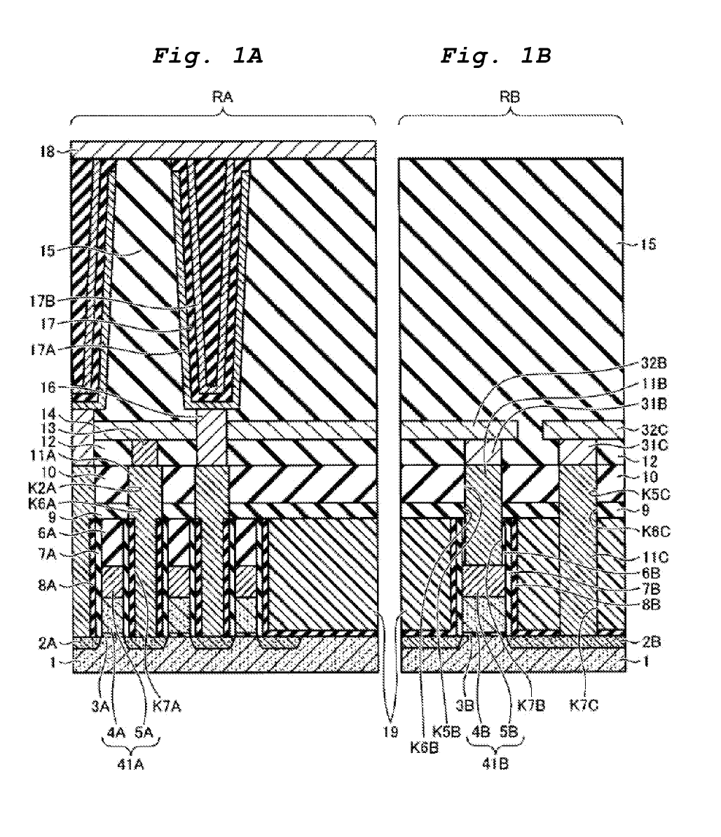

FIG. 1A depicts across section of a cell array part of the semiconductor device of the first embodiment, and FIG. 1B depicts a cross section of a peripheral circuit part of the semiconductor device of the first embodiment. Here, in the first embodiment, DRAM is provided as an example of the semiconductor device.

In FIG. 1A and FIG. 1B, a memory cell part RA and a peripheral circuit part RB are formed on a semiconductor substrate 1. Here, the material of the semiconductor substrate 1, for example, can be selected from Si, Ge, SiGe, GaAs, AlGaAs, InP, GaInAsP, GaP, InGaAs, GaN, SiC, etc. In the memory cell part RA, memory cells can be arranged in a matrix form in the row direction and the column direction. In the peripheral circuit part RB, peripheral circuits, such as row decoders and color decoders, and sense amplifiers can be arranged.

In addition, a gate electrode 41A is formed via a gate-insulating film 3A on the semiconductor substrate 1. Here, the material of the gate-insulating film 3A, for example, can be selected from SiO₂, HfO, HfSiO, HfSiON, HfAlO, HfAlSiON, La₂O₃, etc. Moreover, the gate electrode 41A can be constituted with a two-layer structure of a polycrystalline silicon layer 4A and a tungsten layer 5A.

On the semiconductor substrate 1, an impurity diffusion layer 2A is arranged so that it sandwiches a channel region that is formed on the semiconductor substrate 1 under the gate electrode 41A. Here, the impurity diffusion layer 2A can be used as a source/drain of a transistor of the memory cell part RA. On the gate electrode 41A, a hard mask layer 6A is formed. Here, SiO₂, for example, can be used as the material of the hard mask layer 6A. The hard mask layer 6A can be used as an etching mask for forming the gate electrode 41A as a pattern.

Aside wall insulating film 7A is formed at the side walls of the gate electrode 41A and the hard mask layer 6A, and stopper film 8A is formed on the side surface of the side wall-insulating film 7A. Here, an inorganic insulating film such as SiO₂, for example, can be used as the material of the side-wall insulating film 7A. An inorganic insulating film such as Si₃N₄, for example, can be used as the material of the stopper film 8A.

In addition, on the semiconductor substrate 1, an organic insulating layer 19 is formed at the periphery of the gate electrode 41A and the hard mask layer 6A. Here, the organic insulating layer 19, a low-k film such as polyallyl ether (PAE: Poly Arylene Ether) film, can be used. The organic insulating layer 19 may also be spread low-k films such as polysiloxane, BCB (Benzocyclobutene), fluoropolymer, and polyimide.

A stopper film 9 is formed on the organic insulating film 19 and the hard mask layer 6A, and a hard mask layer 10 is formed on the stopper film 9. Si₃N₄, for example can be used as the material of the stopper film 9. SiO₂, for example, can be used as the material of the hard mask layer 10.

An opening part K2A is formed in the hard mask layer 10, and an opening part K6A is formed in the stopper film 9. The opening parts K2A and K6A are arranged in the organic insulating layer 19 to be embedded between the gate electrodes 41A. A contact hole K7A for exposing the impurity diffusion layer 2A is formed in the organic insulating layer 19. Here, the contact hole K7A is arranged right under the opening parts K2A and K6A. In addition, a contact electrode 11A connected to the impurity diffusion layer 2A is embedded in the opening parts K2A and K6A and the contact hole K7A. Here, a metal such as W or Cu can be used as the material of the contact electrode 11A.

An interlayer dielectric 12 is formed on the contact electrode 11A and the hard mask layer 10. A bit line 14 is formed on the interlayer dielectric 12, and a plug electrode 13 is embedded in the interlayer dielectric 12. Moreover, the bit line 14 is connected to the drain of the impurity diffusion layer 2A via the plug electrode and the contact electrode 11A. An interlayer dielectric 15 is formed on the bit line 14 and the interlayer dielectric 12. A plate line 18 is formed on the interlayer dielectric 15, a capacitor 17 is embedded in the interlayer dielectric 15, and a plug electrode 16 is embedded in the interlayer dielectric 12. Here, capacitive electrodes 17A and 17B arranged opposite to each other make up the capacitor 17. Furthermore, the capacitive electrode 17A is connected to the source of the impurity diffusion layer 2A via the plug electrode and the contact electrode 11A. The capacitive electrode 17B is connected to the plate line 18.

In the peripheral circuit part RB, a gate electrode 41B is formed via a gate-insulating film 3B on the semiconductor substrate 1. Here, the material of the gate insulating film 3B, for example, can be selected from SiO₂, HfO, HfSiO, HfSiON, HfAlO, HfAlSiON, La₂O₃, etc. In addition, the gate electrode 41B can be constituted with a two-layer structure of a polycrystalline silicon layer 4B and a tungsten layer 5B.

On the semiconductor substrate 1, an impurity diffusion layer 2B is arranged so that it sandwiches the channel region that is formed on the semiconductor substrate 1 under the gate electrode 41B. Here, the impurity diffusion layer 2B can be used as a source/drain of a transistor of the peripheral circuit part RB. On the gate electrode 41B, a hard mask layer 6B is formed. SiO₂, for example, can be used here as the material of the hard mask layer 6B. The hard mask layer 6B can be used as an etching mask for forming the gate electrode 41B as a pattern.

Aside wall insulating film 7B is formed at the side wall of the gate electrode 41B and the hard mask layer 6B, and a stopper film 8B is formed on the side surface of the side wall insulating film 7B. An inorganic insulating film such as SiO₂, for example, can be used as the material of the side wall insulating film 7B. An inorganic insulating film such as Si₃N₄, for example, can be used as the material of the stopper film 8B.

Moreover, on the semiconductor substrate 1, the organic insulating layer 19 is formed at the periphery of the gate electrode 41B and the hard mask layer 6B. The stopper film 9 is formed on the organic insulating film 19 and the hard mask layer 6B, and the hard mask layer 10 is formed on the stopper film 9.

Opening parts K5B and K5C are formed in the hard mask layer 10, and opening parts K6B and K6C are formed in the stopper film 9. Here, the opening parts K5B and K6B are arranged on the gate electrodes 41B. The opening parts K5C and K6C are arranged on the peripheral organic insulating layer 19 of the gate electrode 41B. A contact hole K7B for exposing the gate electrode 41B is formed in the hard mask layer 6B. A contact hole K7C for exposing the impurity diffusion layer 2B is formed in the organic insulating layer 19. Here, the contact hole K7B is arranged right under the opening parts K5B and K6B. The contact hole K7C is arranged right under the opening parts K5C and K6C. Furthermore, a contact electrode 11B connected to the gate electrode 41B is embedded in the opening parts K5B and K6B and the contact hole K7B. The contact electrode 11C connected to the impurity diffusion layer 2B is embedded in the opening parts K5C and K6C and the contact hole K7C. Here, metals such as W or Cu can be used as the materials of the contact electrodes 11B and 11C.

The interlayer dielectric 12 is formed on the contact electrodes 11B and 11C and the hard mask layer 10. Wirings 32B and 32C are formed on the interlayer dielectric 12, and plug electrodes 31B and 31C are embedded in the interlayer dielectric 12. In addition, the wiring 32B is connected to the contact electrode 11B via the plug electrode 31B. The wiring 32C is connected to the contact electrode 11C via the plug electrode 31C. The interlayer dielectric 15 is formed on the wirings 32B and 32C and the interlayer dielectric 12. Here, the etching selection ratio to the side wall insulating films 7A and 7B and the stopper films 8A and 8B is raised by covering the periphery of the gate electrodes 41A and 41B with the organic insulating layer 19, as compared to the case in which the periphery of the gate electrodes 41A and 41B is covered with an inorganic insulating layer. As a result, the contact hole K7A can be formed between the gate electrodes 41A in a self-aligning manner to further enable miniaturization of the memory cells of the memory cell part RA.

In addition, with the installation of the stopper film 9 and the hard mask layer 10 on the organic insulating layer 19, the contact hole K7B can be formed on the gate electrode 41B while protecting the organic insulating layer 19. After forming the contact hole K7C on the impurity diffusion layer 2B, the contact hole K7A can be formed between the gate electrodes 41A in a self-aligning manner. Consequently, the contact electrodes 11A, 11B, and 11C can be embedded in the contact holes K7A, K7B, and K7C, respectively. This makes it unnecessary to form the contact electrodes 11A, 11B, and 11C in the memory cell part RA and the peripheral circuit part RB by separate processes; therefore, the steps of the process for contact formation can be reduced.

### Second Embodiment

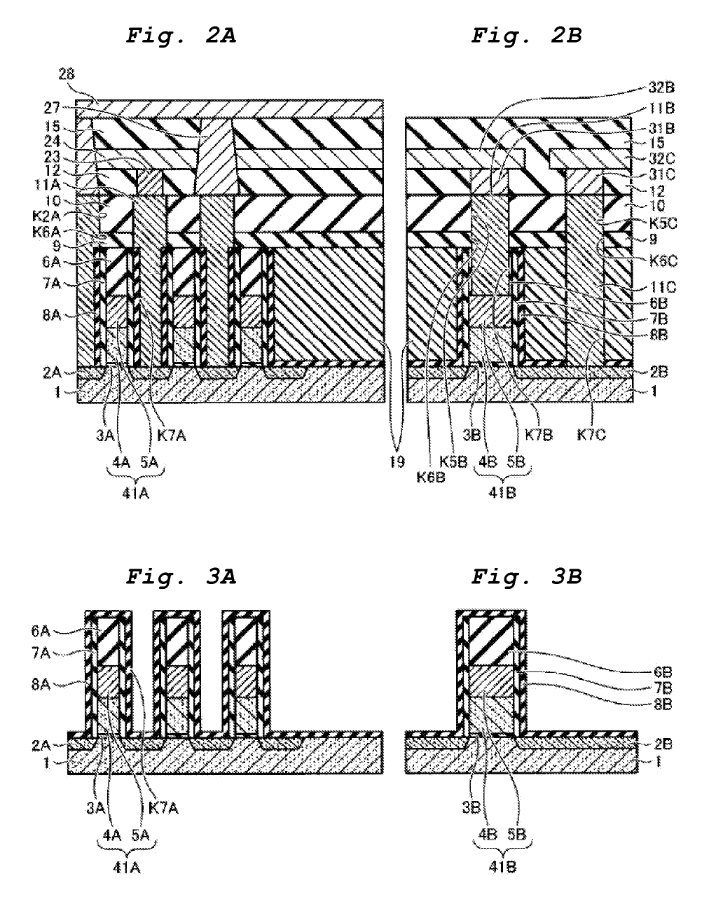

FIG. 2A depicts a cross section of a cell array part of the semiconductor device of the second embodiment, and FIG. 2B depicts a cross section of a peripheral circuit part of the semiconductor device of the second embodiment. Here, in the second embodiment, MRAM is adopted as an example of the semiconductor device.

In FIG. 2A and FIG. 2B, the constitution of the second embodiment is similar to the constitution of FIG. 1A and FIG. 1B except that a magnetic tunnel junction element 27 is used instead of the capacitor 17 of FIG. 1A as a memory element.

In other words, in the memory cell part RA, the interlayer dielectric 12 is formed on the contact electrode 11A and the hard mask layer 10. A bit line 24 is formed on the interlayer dielectric 12, and a plug electrode 23 is embedded in the interlayer dielectric 12. In addition, the bit line 24 is connected to the drain of the impurity diffusion layer 2A via the plug electrode 23 and the contact electrode 11A. An interlayer dielectric 15 is formed on the bit line 24 and the interlayer dielectric 12. A plate line 28 is formed on the interlayer dielectric 15, and the magnetic tunnel junction element 27 is embedded in the interlayer dielectrics 12 and 15. Moreover, one end of the magnetic tunnel junction element 27 is connected to the source of the impurity diffusion layer 2A via the contact electrode 11A, and the other terminal of the magnetic tunnel junction element 27 is connected to the plate line 28.

### Third Embodiment

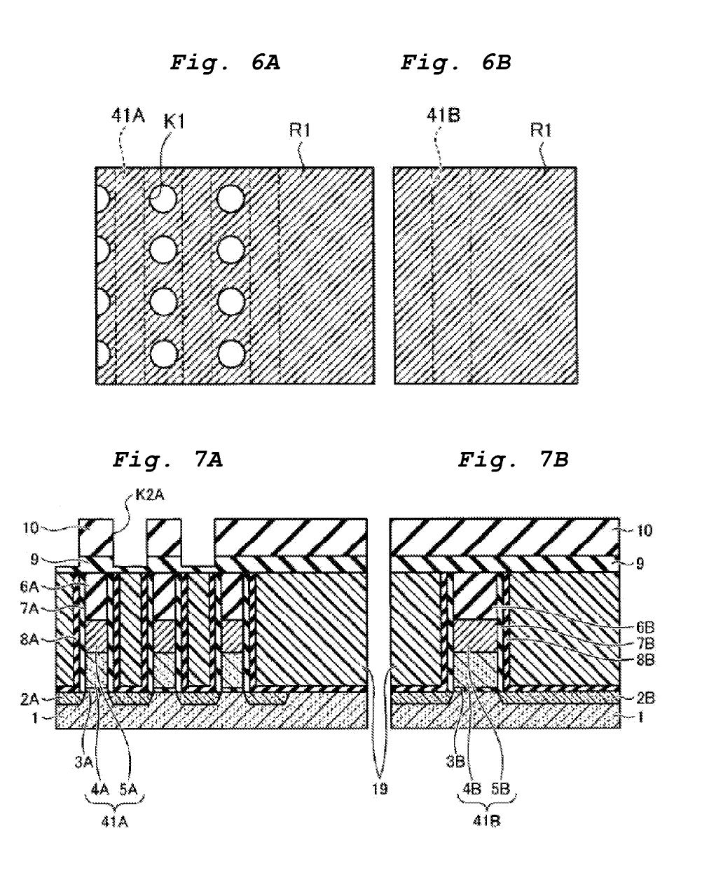

FIG. 3A to FIG. 5A and FIG. 7A to FIG. 14A are cross sections showing the method for manufacturing a cell array part of the semiconductor device of the third embodiment. FIG. 3B to FIG. 5B and FIG. 7B to FIG. 14B are cross sections showing the method for manufacturing a peripheral circuit part of the semiconductor device of the third embodiment. FIG. 6A and FIG. 6B are plan views showing a resist pattern shape that is used in bit contact formation of the cell array part of the semiconductor device of the third embodiment. In the third embodiment, the manufacturing method up to the contact electrodes 11A, 11B, and 11C of FIG. 1A, FIG. 1B, FIG. 2A, and FIG. 2B is shown; the manufacturing method of the capacitor 17 or magnetic tunnel junction element 27 has been omitted.

In FIG. 3A and FIG. 3B, the gate-insulating films 3A and 3B are respectively formed in the memory cell RA and the peripheral circuit part RB on the semiconductor substrate 1 by thermal oxidation method, etc. Next, the polycrystalline silicon layers 4A and 4B, tungsten layers 5A and 5B, and hard mask layers 6A and 6B are respectively formed in the memory cell part RA and the peripheral circuit part RM by CVD method, sputtering method, etc. After the hard mask layers 6A and 6B are patterned by a lithography technique and a dry etching technique, the polycrystalline silicon layers 4A and 4B and the tungsten layers 5A and 5B are pattered through the hard mask layers 6A and 6B so that the gate electrodes 41A and 41B, in which the hard mask layers 6A and 6B have been laminated, are respectively formed in the memory cell part RA and the peripheral circuit part RB.

Next, the side wall insulating films 7A and 7B are respectively formed in the memory cell part RA and the peripheral circuit part RB by CVD method, etc. Through anisotropic etching of the side wall insulating films 7A and 7B by RIE method, etc., the surfaces of the semiconductor substrate 1 and the hard mask layers 6A and 6B are exposed while leaving the side wall insulating films 7A and 7B by RIE method, etc. Next, the stopper films 8A and 8B are respectively formed in the memory cell part RA and the peripheral circuit part RB by CVD method, etc. Using the gate electrodes 41A and 41B as masks, impurities are ion-implanted into the semiconductor substrate 1 to form the impurity diffusion layers 2A and 2B in the memory cell part RA and the peripheral circuit part RB, respectively.

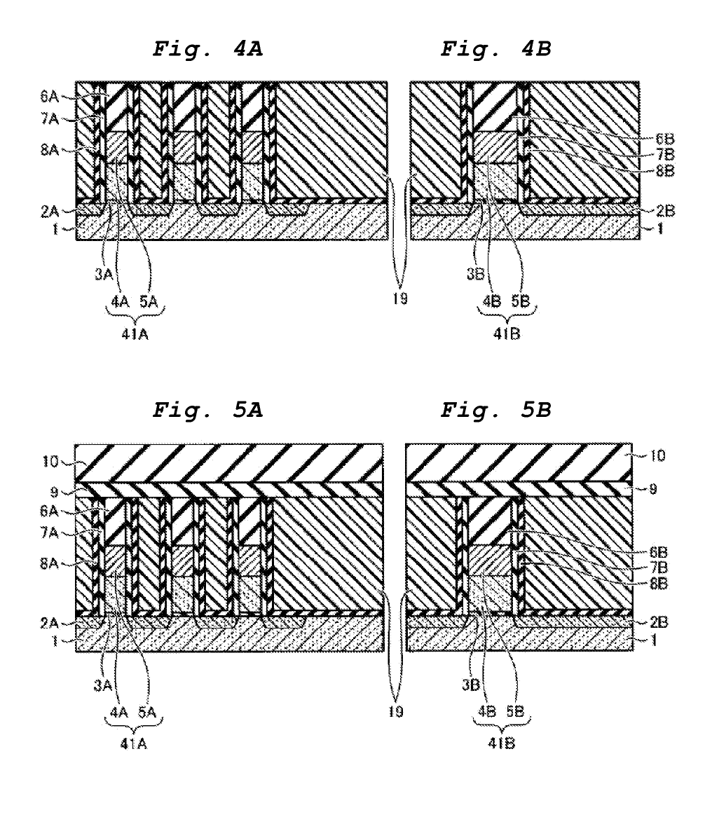

Next, as shown in FIG. 4A and FIG. 4B, the organic insulating layer 19 is formed in the memory cell part RA and the peripheral circuit part RB by the spin-coating method, etc. The organic insulating layer 19 is then flattened by CMP method, etc., to cover the periphery of the gate electrodes 41A and 41B with the organic insulating film 19, exposing the surfaces of the hard mask layers 6A and 6B.

Next, as shown in FIG. 5A and FIG. 5B, the stopper film 9 and the hard mask layer 10 are sequentially formed on the hard mask layers 6A and 6B and the organic insulating layer 19 by CVD method, etc.

Then, as shown in FIG. 6A and FIG. 6B, a resist pattern R1 is formed on the hard mask layer 10 by the lithography technique. Here, an opening part K1 corresponding to the contact hole K7A between the gate electrodes 41A is formed in the resist pattern R1.

In the following step, as shown in FIG. 7A and FIG. 7B, the hard mask layer 10 is etched through the opening part K1 by RIE method, etc., to form the opening K2A, to which the opening part K1 has been transferred, in the hard mask layer 10. At that time, the etching of the hard mask layer 10 can be stopped by the stopper film 9. Next, the resist pattern R1 is removed from the top of the hard mask layer 10 by the asking method, etc. Here, with the installation of the stopper film 9 on the organic insulating layer 19, the organic insulating layer 19 can be prevented from being etched when the resist pattern R1 is removed from the top of the hard mask layer 10.

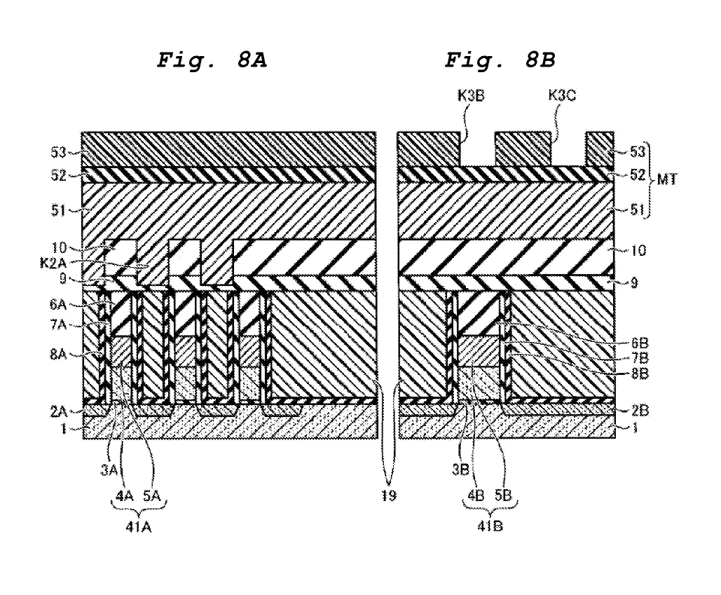

Next, as shown in FIG. 8A and FIG. 8B, a stack mask layer MT is formed on the hard mask layer 10 while the opening part K2A is embedded by spin-coating method, etc. Here, the stack mask layer MT, for example, can adopt a three-layer structure of resist layer 51, hard mask layer 52, and resist layer 53. As the hard mask layer 52, a SOG (Spin On Glass) film can be used. Opening parts K3B and K3C respectively corresponding to the contact holes K7B and K7C are then formed in the resist layer 53 by the lithography technique.

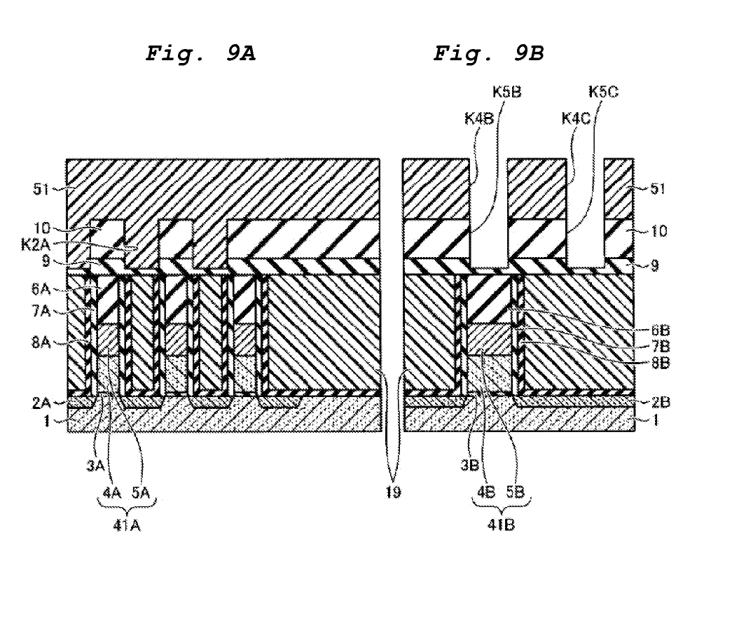

Next, as shown in FIG. 9A and FIG. 9B, the opening parts K3B and K3C are transferred to the hard mask layer 52, and the resist layer 51 is etched via the hard mask layer 52 to form opening parts K4B and K4C in the resist layer 51. In addition, the hard mask layer 10 is etched through the opening parts K4B and K4C to form opening parts K5B and K5C, to which the opening parts K4B and K4C have been transferred, in the hard mask layer 10.

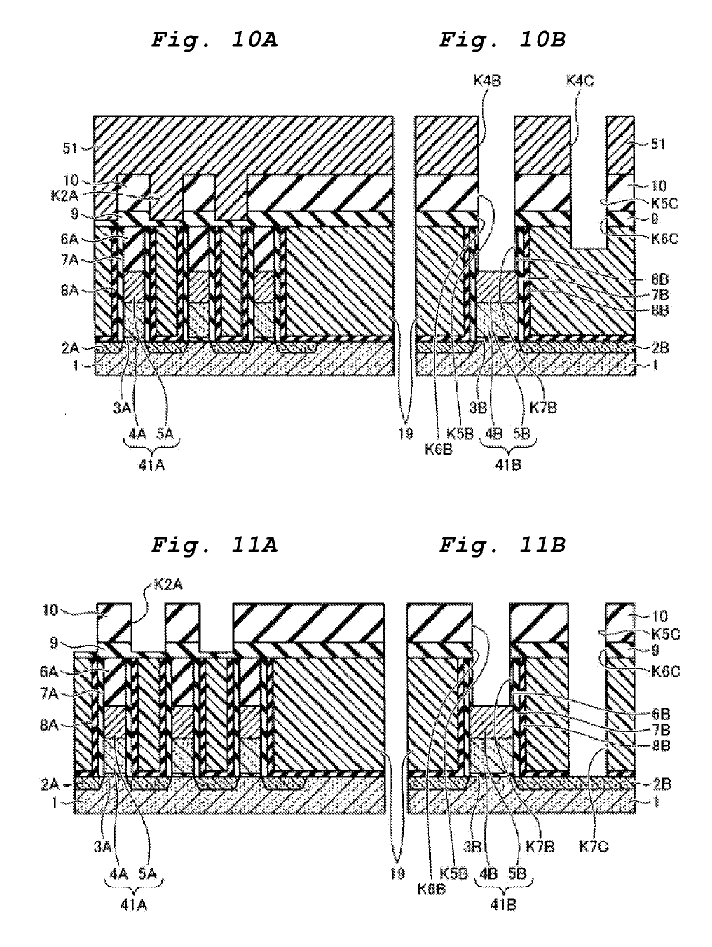

Then, as shown in FIG. 10A and FIG. 10B, using the resist layer 51, in which the opening parts K4B and K4C have been formed, as a mask, the stopper film 9 is etched to form opening parts K6B and K6C, to which the opening parts K4B and K4C have been transferred, in the stopper film 9. In addition, using the resist layer 51, in which the opening parts K4B and K4C have been formed, as a mask, the hard mask layer 6B is etched to form an opening part K7B, to which the opening part K4B has been transferred, in the hard mask layer 6B. Here, the hard mask layer 6B can be made of an inorganic material, and the resist layer 51 and the organic insulating layer 19 can be formed of an organic material. As a result, the etching selection ratio can be increased, as compared with the resist layer 51 and the organic insulating layer 19, thus being able to etch the hard mask layer 6B while suppressing the etching of the resist layer 51 and the organic insulating layer 19.

Next, as shown in FIG. 11A and FIG. 11B, the organic insulating layer 19 is etched through the opening part K5C of the hard mask layer 10, so that the contact hole K7C, to which the opening part K5C has been transferred, is formed in the organic insulating layer 19 and the resist layer 51 is removed from the top of the hard mask layer 10.

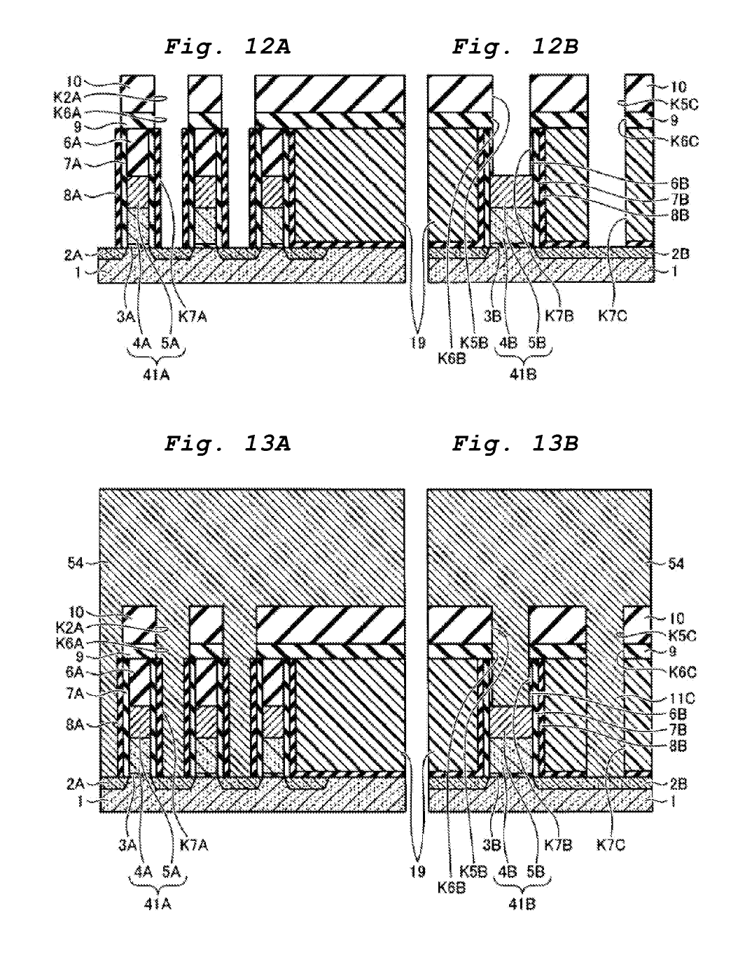

Next, as shown in FIG. 12A and FIG. 12B, the stopper film 9 is etched through the opening part K2A of the hard mask layer 10 to form the opening part K6A, to which the opening part K2A has been transferred, in the stopper layer 9. In addition, the organic insulating layer 19 is etched through the opening parts K2A and K6A to form the contact hole K7A, to which the opening part K2A has been transferred, in the organic insulating layer 19. At that time, with the installation of the stopper film 9 and the hard mask layer 10 on the organic insulating layer 19, the organic insulating layer 19 of the peripheral circuit part RB can be prevented from being etched, thus being able to maintain the shape of the contact holes K7B and K7C.

Next, as shown in FIG. 13A and FIG. 13B, an electrode member 54 is embedded in the opening parts K2A, K5B, K5C, K6A, K6B, and K6B and the contact holes K7A, K7B, and K7C by the CVD method, the sputtering method, etc.

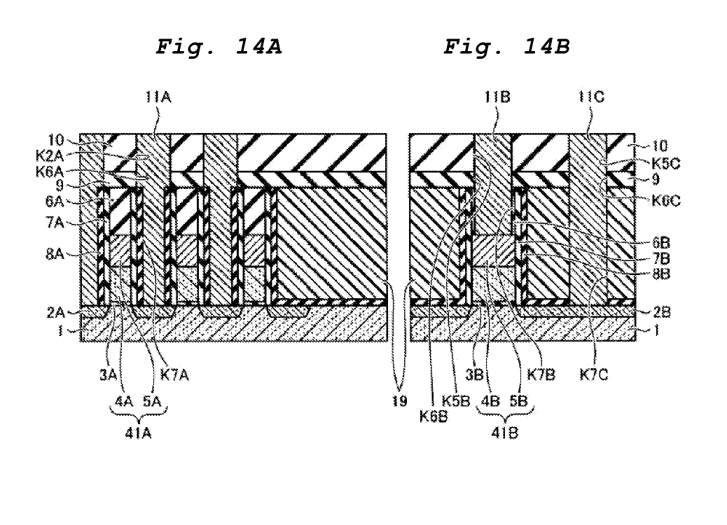

Then, as shown in FIG. 14A and FIG. 14B, the electrode member 54 is flattened by the CMP method, etc., to expose the surface of the hard mask layer 10, collectively forming the contact electrodes 11A, 11B, and 11C respectively embedded in the contact holes K7A, K7B, and K7C. Here, the stopper film 9 and the mask layer 10 are left on the organic insulating layer 19, so that the organic insulating layer 19 can be prevented from being etched in an asking process of the resist film after the formation of the organic insulating layer 19, thereby being able to form the plug electrodes 13, 16, 31B, and 31C, bit line 14, and wirings 32B and 32C of FIG. 1A and FIG. 1B with good precision on the organic insulating layer 19.

### Fourth Embodiment

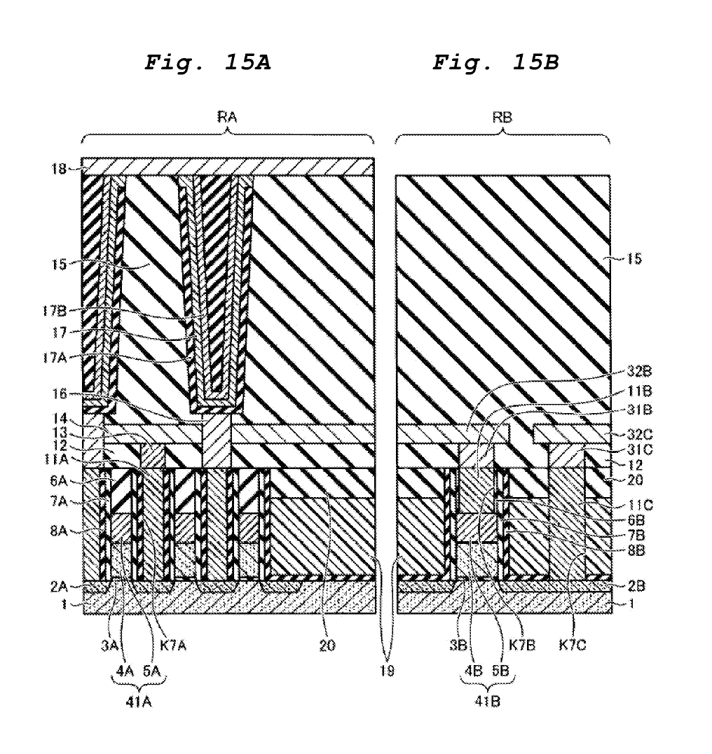

FIG. 15A depicts a cross section of a cell array part of a semiconductor device of the fourth embodiment, and FIG. 15B depicts a cross section of a peripheral circuit part of the semiconductor device of the fourth embodiment. Here, in the fourth embodiment, DRAM is adopted as an example of the semiconductor device.

In FIG. 15A and FIG. 15B, the constitution of the fourth embodiment is similar to the constitution of FIG. 1A and FIG. 1B except that the stopper film 9 and the hard mask layer 10 are removed and an inorganic insulating layer 20 is formed between the organic insulating layer 19 and the interlayer dielectric 12. Here, SiO₂, Si₃N₄, etc., can be used as the material of the inorganic insulating layer 20.

With the installation of the inorganic insulating layer 20 on the organic insulating layer 19, even in case the stopper film 9 and the hard mask layer 10 are removed after respectively embedding the contact electrodes 11A, 11B, and 11C into the contact holes K7A, K7B, and K7C, the organic insulating layer 19 can be protected with inorganic insulating layer 20. As a result, the organic insulating layer 19 can be prevented from being etched in the asking process of the resist film after the formation of the organic insulating layer 19, thus being able to form the plug electrodes 13, 16, 31B, and 31C, bit line 14, and wirings 32B and 32C with good precision on the organic insulating layer 19.

### Fifth Embodiment

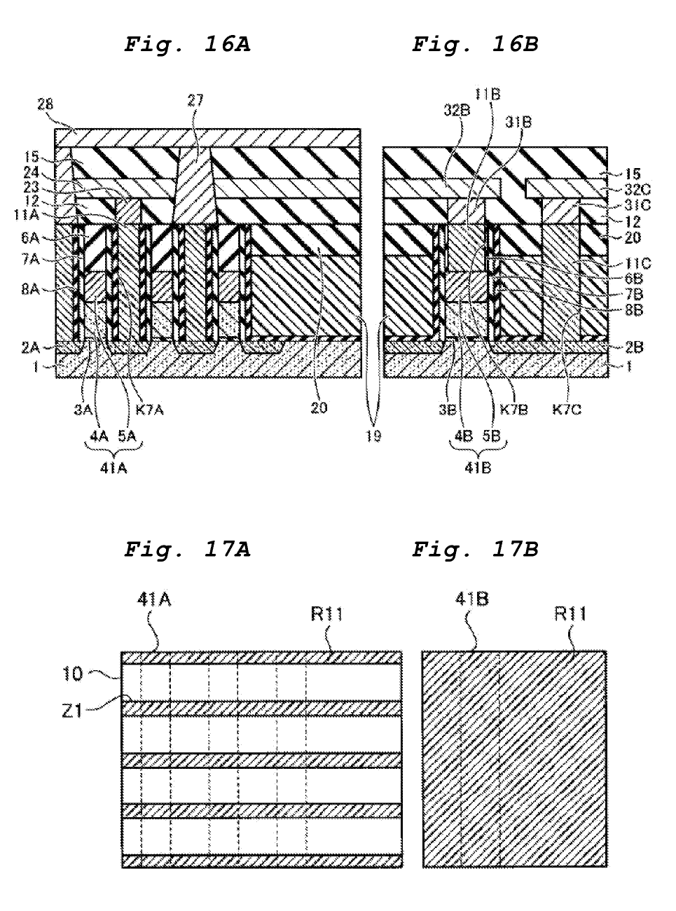

FIG. 16A depicts a cross section of a cell array part of a semiconductor device of the fifth embodiment, and FIG. 16B depicts a cross section of a peripheral circuit part of the semiconductor device of the fifth embodiment. Here, in the fifth embodiment, MRAM has been mentioned as an example of the semiconductor device.

In FIG. 16A and FIG. 16B, the constitution of the fifth embodiment is similar to the constitution of FIG. 2A and FIG. 2B except that the stopper film 9 and the hard mask layer 10 are removed and the inorganic insulating layer 20 is formed between the organic insulating layer 19 and the interlayer dielectric 12.

### Sixth Embodiment

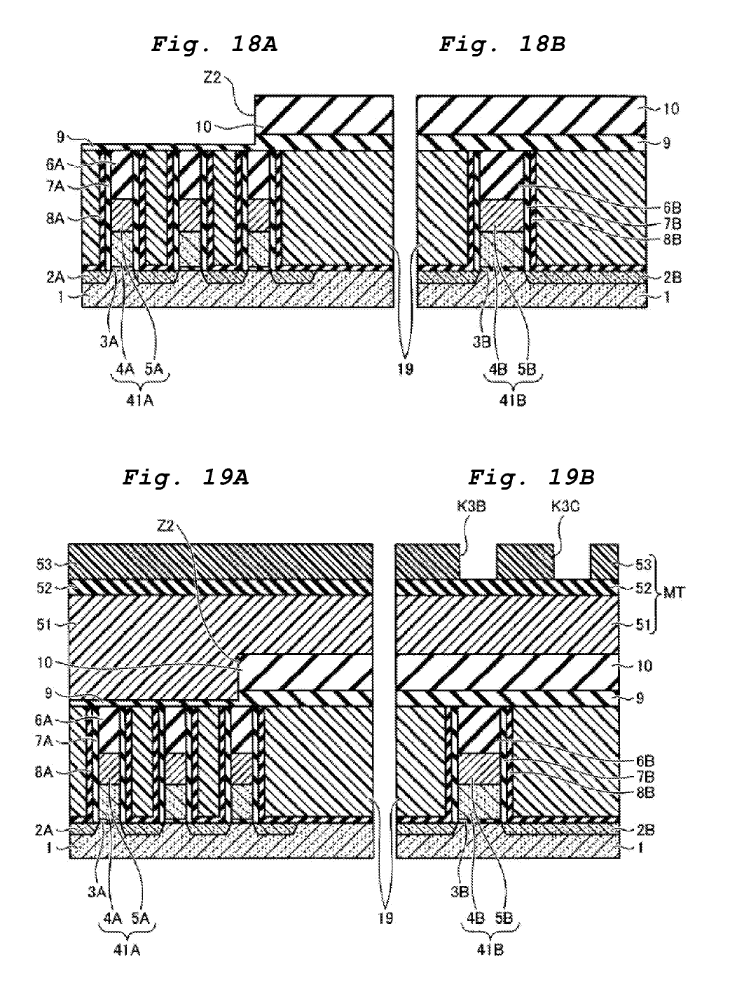

FIG. 17A and FIG. 17B are plan views showing a resist pattern shape that is used in the bit contact formation of a cell array part of a semiconductor device of the sixth embodiment; FIG. 18A to FIG. 28A are cross sections showing the method for manufacturing a cell array part of the semiconductor device of the sixth embodiment; and FIG. 18B to FIG. 28B are cross sections showing the method for manufacturing a peripheral circuit part of the semiconductor device of the sixth embodiment. Here, in the sixth embodiment, the manufacturing method up to the inorganic insulating layer 20 of FIG. 15A, FIG. 15B, FIG. 16A and FIG. 16B is shown, and the manufacturing method of the capacitor 17 or magnetic tunnel junction element 27 is omitted.

In the sixth embodiment, processes similar to those of FIG. 3A to FIG. 5A and FIG. 3B to FIG. 5B are carried out.

Next, as shown in FIG. 17A and FIG. 17B, a resist pattern R11 is formed on the hard mask layer 10 by the lithography technique. Here, a groove Z1 orthogonal to the gate electrode 41A is formed in the resist pattern R11.

Then, as shown in FIG. 18A and FIG. 18B, the hard mask layer 10 is etched through the groove Z1 by RIE method, etc., to form a groove Z2, to which the groove Z1 has been transferred, in the hard mask layer 10. At that time, the etching of the hard mask layer 10 can be stopped by the stopper film 9. The resist pattern R11 is removed from the top of the hard mask layer 10 by the asking method, etc.

Next, as shown in FIG. 19A and FIG. 19B, the stack mask layer MT is formed on the hard mask layer 10 while a groove Z2 is embedded by the spin-coating method, etc. Here, the stack mask layer MT, for example, can adopt a three-layer structure of resist layer 51, hard mask layer 52, and resist layer 53. The opening parts K3B and K3C respectively corresponding to the contact holes K7B and K7C are then formed in the resist layer 53 by the lithography technique.

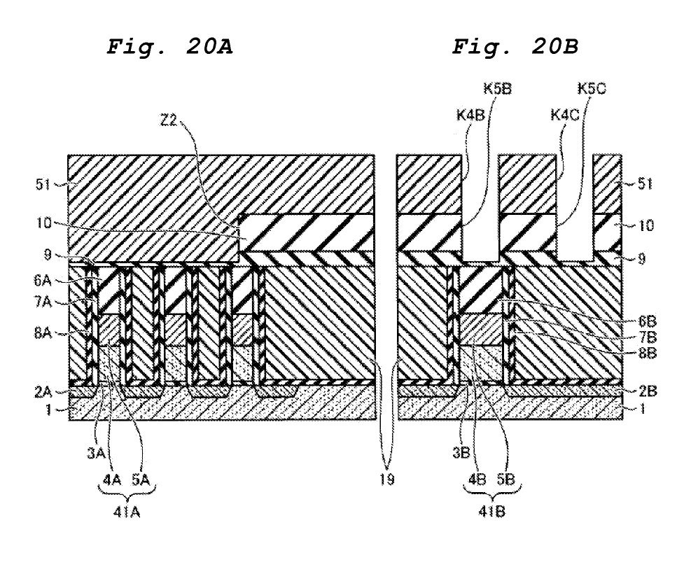

Next, as shown in FIG. 20A and FIG. 20B, the opening parts K3B and K3C are transferred to the hard mask layer 52, and the resist layer 51 is etched via the hard mask layer 52 to form opening parts K4B and K4C in the resist layer 51. In addition, the hard mask layer 10 is etched through the opening parts K4B and K4C to form opening parts K5B and K5C, to which the opening parts K4B and K4C have been transferred, in the hard mask layer 10.

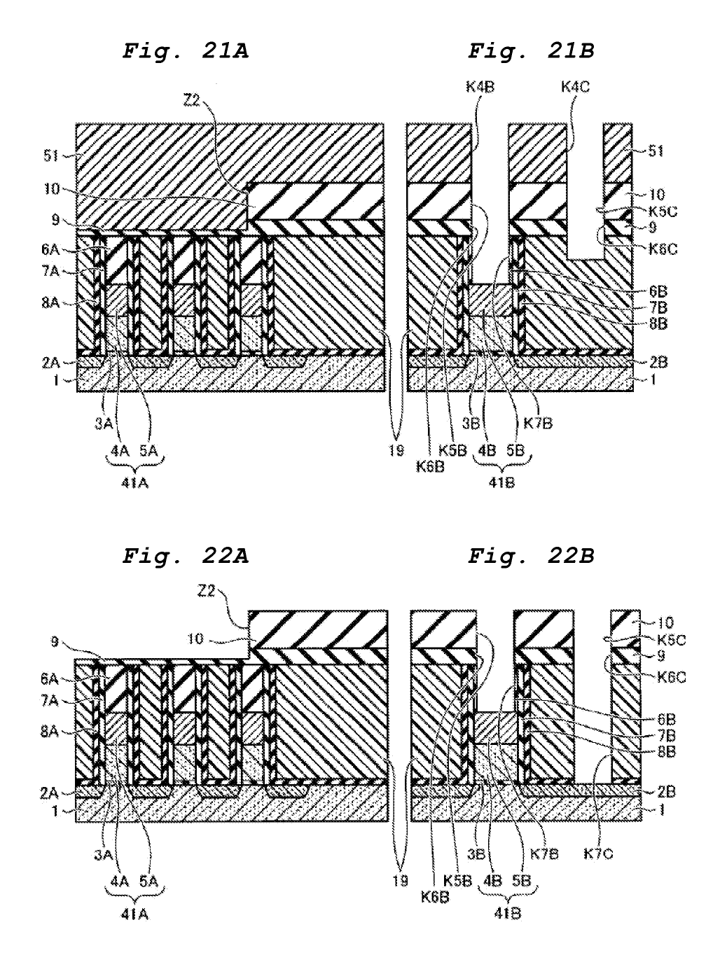

Then, as shown in FIG. 21A and FIG. 21B, using the resist layer 51, in which the opening parts K4B and K4C have been formed, as a mask, the stopper film 9 is etched to form opening parts K6B and K6C, to which the opening parts K4B and K4C have been transferred, in the stopper film 9. In addition, using the resist layer 51, in which the opening parts K4B and K4C have been formed, as a mask, the hard mask layer 6B is etched to form the opening part K7B, to which the opening part K4B has been transferred, in the hard mask layer 6B.

Next, as shown in FIG. 22A and FIG. 22B, the organic insulating layer 19 is etched through the organic insulating layer 19 through the opening part K5C of the hard mask layer 10, so that the contact hole K7C, to which the opening part K5C has been transferred, is formed in the organic insulating layer 19 and the resist layer 51 is removed from the top of the hard mask layer 10.

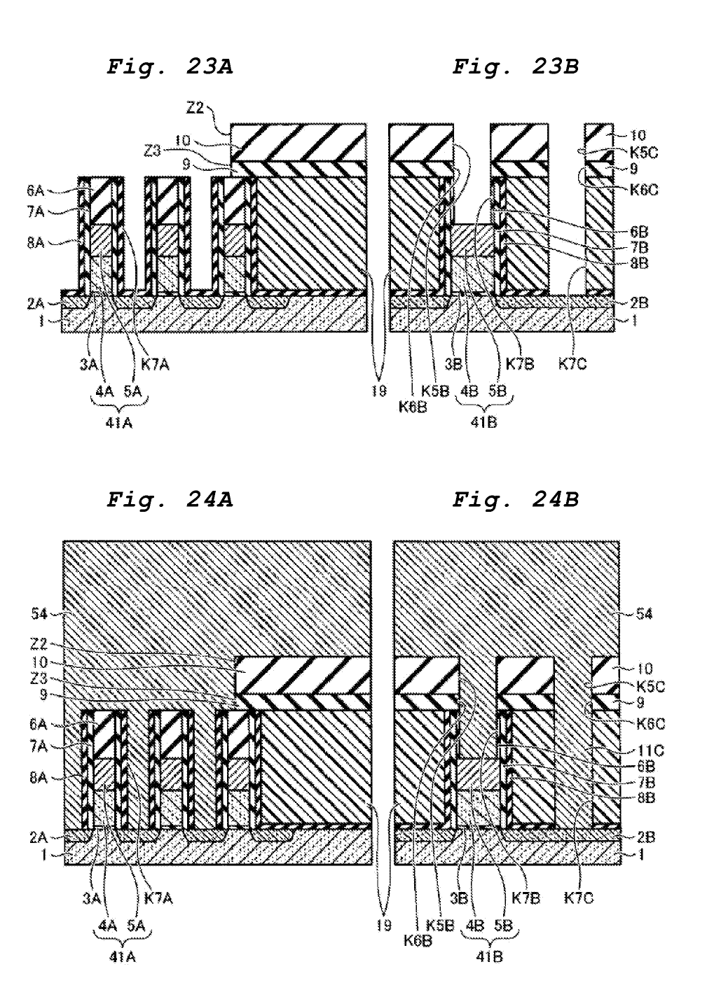

Then, as shown in FIG. 23A and FIG. 23B, the stopper film 9 is etched through the groove Z2 of the hard mask layer 10 to form a groove Z3, to which the groove Z2 has been transferred, in the stopper film 9. In addition, the organic insulating layer 19 is etched through the grooves Z2 and Z3 to remove the organic insulating layer 19 between the gate electrodes 41A along the grooves Z2 and Z3, forming the contact hole K7A arranged in the gate electrode 41A in the organic insulating layer 19. At that time, with the installation of the stopper film 9 and the hard mask layer 10 on the organic insulating layer 19, the organic insulating layer 19 of the peripheral circuit part RB can be prevented from being etched, thus being able to maintain the shape of the contact holes K7B and K7C. Moreover, the organic insulating layer 19 is embedded between the gate electrodes 41A, thus being able to remove the organic insulating layer 19 while leaving the side wall insulating film 7A. As a result, the contact hole K7A can be formed between the gate electrodes 41A without covering the side wall insulating film 7A with a resist film, thus being able to form the contact hole K7A in a self-aligning manner.

Next, as shown in FIG. 24A and FIG. 24B, the electrode member 54 is embedded in the grooves Z2 and Z3 and the opening parts K5B, K5C, K6B and K6C and the contact holes K7A, K7B, and K7C by the CVD method, sputtering method, etc.

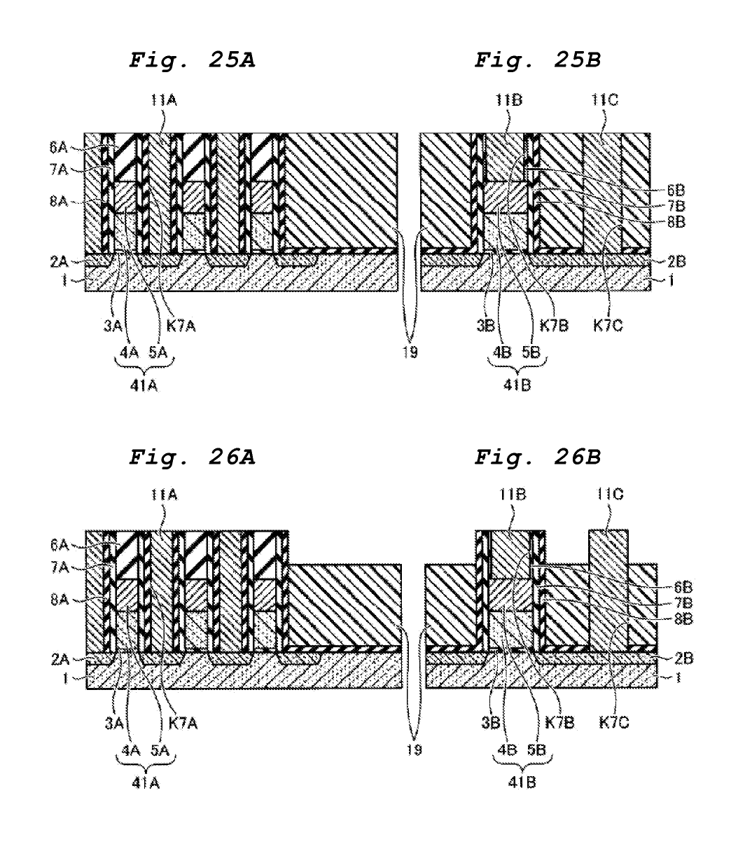

Then, as shown in FIG. 25A and FIG. 25B, the electrode member 54 is flattened by the CMP method, etc., and the hard mask layer 10 and the stopper film 9 are removed, so that the surfaces of the hard mask layer 6A and the organic insulating layer 19 are exposed, thereby collectively forming the contact electrodes 11A, 11B, and 11C respectively embedded in the contact holes K7A, K7B, and K7C.

Next, as shown in FIG. 26A and FIG. 26B, the organic insulating layer 19 is etched back by the RIE method, etc., to remove the upper part of the organic insulating layer 19, forming a step difference for the gate electrodes 41A and 41B.

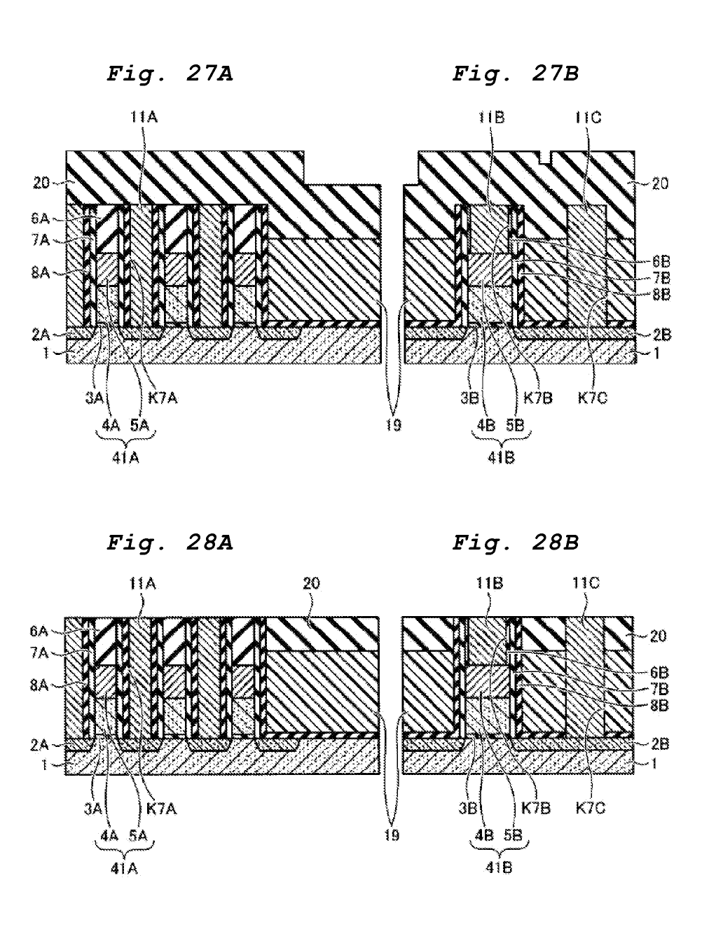

Then, as shown in FIG. 27A and FIG. 27B, the inorganic insulating layer 20 is formed on the hard mask layer 6A, contact electrodes 11A, 11B, and 11C, and organic insulating layer 19 by the CVD method, etc., while the part from which the organic insulating layer 19 has been removed is embedded. SiO₂, Si₃N₄, etc., can be used as the material of the inorganic insulating layer 20.

Next, as shown in FIG. 28A and FIG. 28B, the inorganic insulating layer 20 is flattened by the CMP method, etc., to expose the surfaces of the hard mask layer 6A and the contact electrodes 11A, 11B, and 11C, so that the heights of the hard mask layer 6A and the contact electrodes 11A, 11B, and 11C are aligned.

Here, with the installation of the inorganic insulating layer 20 on the organic insulating layer 19, the organic insulating layer 19 can be prevented from being etched in an asking process of the resist film after the formation of the organic insulating layer 19, thereby being able to form the plug electrodes 13, 16, 31B, and 31C, bit line 14, and wirings 32B and 32C of FIG. 15A and FIG. 15B with good precision on the organic insulating layer 19.

Here, in the embodiments, semiconductor devices such as DRAM and MRAM have been adopted as the semiconductor devices; however, the present disclosure may be applied to semiconductor devices such as ASIC, processors, or logic circuits. In addition, the present disclosure may also be applied to NAND flash memories along with the DRAM or MRAM.

While certain embodiments have been described, these embodiments have been presented by way of example only and are not intended to limit the scope of the inventions. Indeed, the novel embodiments described herein may be embodied in a variety of other forms;

furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a gate electrode formed on a semiconductor substrate;
a channel region formed on the semiconductor substrate under the gate electrode and an impurity diffusion layer formed on the semiconductor substrate on either side of the gate electrode;
a side wall insulating film formed at side walls of the gate electrode;
an organic insulating layer covering a periphery of the gate electrode;
an inorganic insulating layer formed on the gate electrode and the organic insulating layer; and
a contact electrode that is embedded in the inorganic insulating layer and the organic insulating layer and connected to the impurity diffusion layer.

2. The semiconductor device of claim 1, further comprising a memory cell region and a peripheral circuit region and the gate electrode is formed in one of the memory cell region and the peripheral circuit region.

3. The semiconductor device of claim 2, wherein the other one of the memory cell region and the peripheral circuit region includes:
a second gate electrode formed on the semiconductor substrate;
a second channel region formed on the semiconductor substrate under the second gate electrode and a second impurity diffusion layer formed on the semiconductor substrate on either side of the second gate electrode; and
a second side wall insulating film formed at side walls of the second gate electrode,
wherein the organic insulating layer also covers a periphery of the second gate electrode and the inorganic insulating layer is also formed on the second gate electrode.

4. The semiconductor device of claim 3, wherein the other one of the memory cell region and the peripheral circuit region further includes:
a second contact electrode that is embedded in the inorganic insulating layer and the organic insulating layer and connected to the second impurity diffusion layer.

5. The semiconductor device of claim 4, further comprising a third contact electrode that is embedded in the inorganic insulating layer and the organic insulating layer and connected to the second gate electrode.

6. The semiconductor device of claim 3, wherein the gate electrodes of the memory cell region and the peripheral circuit region each have a laminated structure including a hard mask layer.

7. The semiconductor device of claim 6, wherein the hard mask layer is the uppermost layer in contact with the inorganic insulating layer.

8. The semiconductor device of claim 1, wherein there is no organic insulating layer between the contact electrode and the side wall insulating film.

9. A method for manufacturing a semiconductor device, comprising:
forming a first gate electrode, in which a first hard mask is laminated, on a first part of a semiconductor substrate, and forming a second gate electrode, in which a second hard mask is laminated, on a second part of the semiconductor substrate;
forming a first side wall insulating film on the side wall of the first gate electrode and forming a second side wall insulating film on the side wall of the second gate electrode;
forming a first impurity diffusion layer at the side of the first gate electrode on the semiconductor substrate and forming a second impurity diffusion layer at the side of the second gate electrode on the semiconductor substrate;
forming an organic insulating layer, which covers the first and second gate electrode and the periphery of the first and second hard masks, on the semiconductor substrate;
forming a stopper film on the first and second hard masks and the organic insulating layer;
forming a third hard mask on the stopper film;
forming a first opening above the organic insulating layer that covers the periphery of the first gate electrode in the third hard mask;
forming a resist layer on the third hard mask in which the first opening has been formed;
forming a second opening above the second gate electrode and the organic insulating layer that covers the periphery of the second gate electrode in the resist layer;
forming a first contact hole above the second gate electrode by etching the third hard mask, the stopper film, and the second hard mask through the second opening and forming a third opening on the organic insulating film that covers the periphery of the second gate electrode;
forming a second contact hole above the second impurity diffusion layer by etching the organic insulating layer through the third opening and removing the resist layer;
forming a third contact hole above the first impurity diffusion layer by etching the stopper film and the organic insulating layer through the first opening; and
embedding first, second, and third contact electrodes into the first, second, and third contact holes, respectively.

10. The method of claim 9, wherein the first part of the semiconductor substrate is a memory cell part and the second part of the semiconductor substrate is a peripheral circuit part.

11. The method of claim 9, wherein the first opening includes a plurality of cylindrical openings in the third hard mask.

12. The method of claim 9, wherein the first opening includes a groove in the third hard mask.

13. The method of claim 12, wherein the first gate electrode extends along a first direction and the groove extends along a second direction that is orthogonal to the first direction.

14. A semiconductor device, comprising:
a memory cell formed on a semiconductor substrate; and
a control circuit for the memory cell formed on the semiconductor substrate,
wherein each of the memory cell and the peripheral circuit includes:
a gate electrode formed on a semiconductor substrate;
an impurity diffusion layer arranged so that it sandwiches a channel region that is formed on the semiconductor substrate under the gate electrode;
a side wall insulating film formed at the side walls of the gate electrode;
an organic insulating layer for covering a periphery of the gate electrode;
an inorganic insulating layer formed on the gate electrode and the organic insulating layer; and
a contact electrode that is embedded in the inorganic insulating layer and the organic insulating layer and connected to the impurity diffusion layer.

15. The semiconductor device of claim 14, wherein the same insulating layer covers the peripheries of the gate electrodes of the memory cell and the control circuit.

16. The semiconductor device of claim 15, wherein the same inorganic insulating layer is formed on the gate electrodes of the memory cell and the control circuit.

17. The semiconductor device of claim 14, further comprising an additional contact electrode that is embedded in the inorganic insulating layer and the organic insulating layer and connected to the second gate electrode.

18. The semiconductor device of claim 14, wherein there is no organic insulating layer between the contact electrodes of the memory cell and the control circuit and the corresponding side wall insulating film.

19. The semiconductor device of claim 14, wherein the gate electrodes of the memory cell region and the peripheral circuit region each have a laminated structure including a hard mask layer.

20. The semiconductor device of claim 19, wherein the hard mask layer is the uppermost layer in contact with the inorganic insulating layer.
